(19) United States
(12) Patent Application Publication
(10) Pub. No.: US 2013/0099813 A1
(43) Pub. Date: Apr. 25, 2013

(54) CONTACT TERMINAL FOR A PROBE CARD, AND THE PROBE CARD

(71) Applicant: TOKYO ELECTRON LIMITED, Tokyo (JP)

(72) Inventors: Tomohisa HOSHINO, Yamanashi (JP); Takashi Amemiya, Yamanashi (JP)

(73) Assignee: TOKYO ELECTRON LIMITED, Tokyo (JP)

(21) Appl. No.: 13/656,069

(22) Filed: Oct. 19, 2012

(30) Foreign Application Priority Data
Oct. 21, 2011 (JP) 2011-231673

(51) Int. Cl. G01R 1/067; G01R 31/26

(52) U.S. Cl. 324/755.01; 324/756.03

(57) ABSTRACT

A contact terminal for a probe card includes a cylindrical main body. The main body includes a pillar-shaped central portion formed of a first material and an outer housing which is formed of a second material and covers a lateral surface of the central portion, and hardness and resistivity of the second material are different from hardness and resistivity of the first material. The hardness of the second material is higher than that of the first material and the resistivity of the first material is lower than that of the second material, or the hardness of the first material is higher than that of the second material and the resistivity of the second material is lower than that of the first material.

### CROSS-REFERENCE TO RELATED APPLICATION

This application claims priority to Japanese Patent Application No. 2011-231673 filed on Oct. 21, 2011, the entire contents of which are incorporated herein by reference.

### FIELD OF THE INVENTION

The present invention relates to a contact terminal for a probe card and the probe card.

### BACKGROUND OF THE INVENTION

A probe is used as a detecting unit to examine each semiconductor device formed on a wafer. The probe includes a stage on which a wafer is mounted and a probe card to face the stage. The probe card includes a plate-shaped base and cylindrical contact terminals, such as plungers or contact probes of pogo pins (spring probes), disposed on a surface of the base facing the stage to face electrode pads or solder bumps of the semiconductor device of the wafer (e.g., see Japanese Application Publication No. 2002-22768).

In the probe, when the wafer mounted on the stage faces the probe card, the respective contact terminals of the probe card are brought in contact with the electrode pads or solder bumps of the semiconductor device, and electricity is applied from each contact terminal to an electric circuit of the semiconductor device connected to each electrode pad or solder bump, thereby examining conducting state of the electric circuit.

Recently, with a miniaturization of an electric circuit of a semiconductor device, an electrode pad or solder bump is also miniaturized, and therefore, the size of a contact terminal of a probe card decreases. However, a smaller contact terminal involves increase in the contact pressure between the electrode pad and the contact terminal, resulting in severe abrasion of the contact terminal. In order to prevent the abrasion of the contact terminal, the contact terminal is formed of a high abrasion resistant material having high hardness.

### SUMMARY OF THE INVENTION

However, high abrasion resistant materials generally have a high resistivity, and the contact terminal has reduced electric current conductance due to its smaller size, and thus, the resistance of the contact terminal increases. Thus, when an electric current is applied to the contact terminal, the contact terminal emits a heat not only to be oxidized but to oxidize surrounding contact terminals. In addition, when the amount of heat emitted by the contact terminal is remarkable, the contact terminal may be damaged by melting.

In view of the above, the present invention is to provide a contact terminal for a probe card and the probe card for preventing oxidation and damage of the contact terminal.

In accordance with an aspect of the present invention, there is provided a contact terminal for a probe card including a cylindrical main body. The main body has a pillar-shaped central portion formed of a first material and an outer housing which is formed of a second material and covers a lateral surface of the central portion. Hardness and resistivity of the second material are different from hardness and resistivity of the first material.

The hardness of the second material may be higher than that of the first material, and the resistivity of the first material may be lower than that of the second material.

The hardness of the first material may be higher than that of the second material, and the resistivity of the second material may be lower than that of the first material.

A contact portion of the main body to be contacted with a semiconductor device is preferably cone-shaped.

The contact portion of the main body to be contacted with a semiconductor device preferably has a cannon ball shape.

The contact portion of the main body to be contacted with a semiconductor device may be cylinder end-shaped.

The contact portion of the main body with a semiconductor device may be formed by cutting the main body along a surface inclined with respect to an axis of the main body.

The central portion may have a thickness in a range from about 0.5 μm to 50 μm and the outer housing has a thickness in a range from about 0.5 μm to 100 μm.

The central portion may have a thickness in a range from about 0.5 μm to 50 μm and the outer housing has a thickness in a range from about 0.5 μm to 100 μm.

In accordance with another aspect of the present invention, there is provided a probe card for examining a semiconductor device formed on a semiconductor substrate. The probe card includes: a plate-shaped base; and contact terminals for the probe card disposed on a surface of the base facing the semiconductor substrate. Each of the contact terminals includes a cylindrical main body, the main body has a pillar-shaped central portion formed of a first material and an outer housing which is formed of a second material and covers a lateral surface of the central portion, and hardness and resistivity of the second material are different from hardness and resistivity of the first material.

### BRIEF DESCRIPTION OF THE DRAWINGS

The objects and features of the present invention will become apparent from the following description of preferred embodiments given in conjunction with the accompanying drawings, in which:

FIG. 1 is a perspective view schematically illustrating a configuration of a probe card in accordance with an embodiment of the present invention;

FIG. 2 is an enlarged cross-sectional view schematically illustrating a configuration of a pogo pin shown in FIG. 1;

FIG. 3 is an enlarged cross-sectional view of a contact portion of a plunger of the pogo pin shown in FIG. 2; and

FIGS. 4A to 4C show modifications of a tip portion of the contact portion shown in FIG. 3, wherein FIG. 4A is a first modification, FIG. 4B is a second modification, and FIG. 4C is a third modification.

### DETAILED DESCRIPTION OF THE EMBODIMENTS

Hereinafter, embodiments of the present invention will be described with reference to the accompanying drawings which form a part hereof.

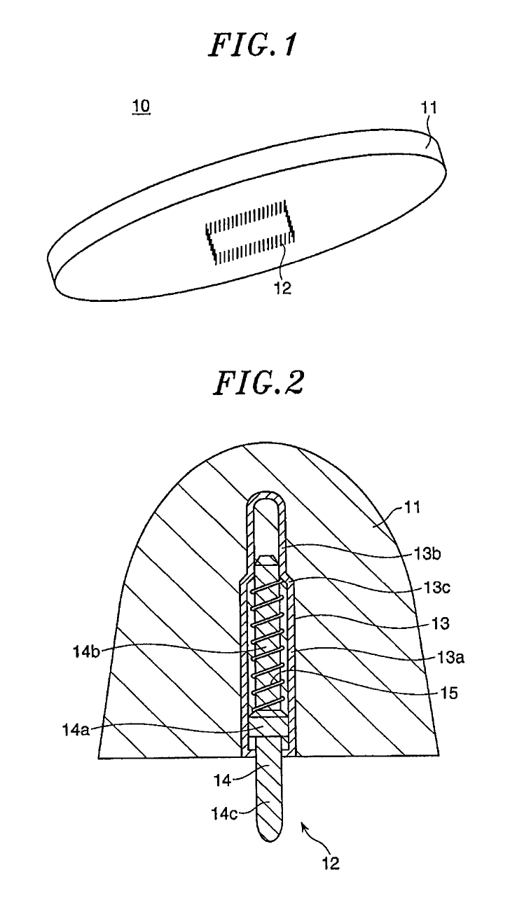

FIG. 1 is a perspective view schematically illustrating a configuration of a probe card in accordance with the embodiment of the present invention.

Referring to FIG. 1, the probe card 10 includes a circular plate-shaped base 11 (base portion) and pogo pins 12 disposed on a surface of the base 11 facing a semiconductor wafer (the bottom surface in FIG. 1).

The pogo pins 12 are disposed corresponding to electrode pads or solder bumps arranged on a semiconductor device formed on the semiconductor wafer, and thus, tips thereof can be brought in contact with the respective electrode pads or solder bumps when the probe card 10 faces the semiconductor wafer.

FIG. 2 is an enlarged cross-sectional view schematically illustrating a configuration of the pogo pin 12 shown FIG. 1.

Referring to FIG. 2, the pogo pin 12 includes a tube-shaped outer case 13, a cylindrical plunger 14 (contact terminal for a probe card) slidably fitted in the outer case 13 and a coil spring 15. The outer case 13 is a stepped case including a lower portion 13a of relatively large diameter, an upper portion 13b of relatively small diameter and a shoulder portion 13c formed between the lower portion 13a and the upper portion 13b. The plunger 14 includes a guide portion 14a of a relatively large diameter which is slidably fitted to the lower portion 13a, an upper axis portion 14b of relatively small diameter which is slidably fitted to the upper portion 13b and a contact portion 14c (main body) extending in the opposite direction from the upper axis portion 14b with the guide portion 14a interposing therebetween and having a smaller diameter than that of the guide portion 14a.

The coil spring 15 is disposed between the shoulder portion 13c of the outer case 13 and the guide portion 14a of the plunger 14. When the pogo pin 12 is brought in contact with an electrode pad so that the plunger 14 is pressed into the outer case 13, the coil spring 15 is compressed to generate a resilience force, and accordingly the contact portion 14c of the plunger 14 is extruded back toward the electrode pad. As a result, the contact portion 14c can be kept in contact with the electrode pad.

In the probe card 10, the outer case 13 of each pogo pin 12 is embedded in the base 11, so that only the plunger 14 is protruded from the bottom surface of the probe card 10. Further, an electric current flows in each pogo pin 12 and flows into an electrode pad or solder bump in contact with the pogo pin 12.

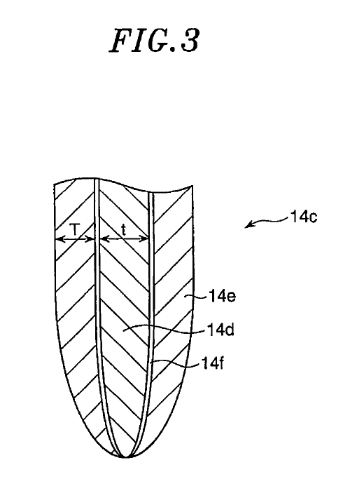

FIG. 3 is an enlarged cross-sectional view of the contact portion 14c of the plunger 14 of the pogo pin 12 shown in FIG. 2.

Referring to FIG. 3, the contact portion 14c includes a pillar-shaped central portion 14d, an outer housing 14e covering the lateral surface of the central portion 14d, and an adhesion layer 14f interposed between the central portion 14d and the outer housing 14e to adhere the central portion 14d and the outer housing 14e. A part of the contact portion 14c which comes in contact with the electrode pad (hereinafter, referred to as a tip portion) has a cannon ball shape. Accordingly, even if the contact portion 14c inclines to the electrode pad, a contact form between the contact portion 14c and the electrode pad does not change abruptly and a contact pressure can be maintained to be almost constant. Further, in the present embodiment, the outer housing 14e covers the lateral surface of the central portion 14d to the tip end of the contact portion 14c.

The central portion 14d and the outer housing 14e are formed of different materials. In detail, the hardness and the resistivity of a material for the outer housing 14e (a second material, hereinafter, referred to as an outer material) are different from those of a material for the central portion 14d (a first material, hereinafter, referred to as an central material).

In the present embodiment, as a combination of the central material and the outer material, there is used a combination in which the outer material includes a high abrasion resistant material having a higher hardness than that of the central material and the central material includes a low resistance material having a lower resistivity than that of the outer material (hereinafter, referred to as a first combination) or a combination in which the central material includes a high abrasion resistant material having a higher hardness than that of the outer material and the outer material includes a low resistance material having a lower resistivity than that of the central material (hereinafter, referred to as a second combination).

In the first combination, even if the contact portion 14c is repeatedly brought in contact with the electrode pad, the outer housing 14e is not worn out and the abrasion of the central portion 14d adjacent to the outer housing 14e is prevented, thus suppressing the deformation of the contact portion 14c. Further, when the contact portion 14c is brought in contact with the electrode pad, the central portion 14d smoothly flows an electric current to make high conductivity, thereby preventing the contact portion 14c from heat emission and consequently preventing the contact portion 14c from being oxidized and damaged by melting.

Further, in the second combination, even if the contact portion 14c is repeatedly brought in contact with the electrode pad, the central portion 14d is not worn out and the abrasion of the outer housing 14e adjacent to the central portion 14d is prevented, thus suppressing the deformation of the contact portion 14c. Further, when the contact portion 14c is brought in contact with the electrode pad, the outer housing 14e smoothly flows an electric current to obtain high conductivity, thereby preventing the contact portion 14c from emitting a heat and consequently preventing the contact portion 14c from being oxidized and damaged by melting.

The low resistance material to be used in the present embodiment preferably has not only a low resistivity but a high specific heat and a low thermal conductivity. With high specific heat, it is hard for the temperature of the low resistance material to increase even when a high electric current flows to the contact portion 14c to generate a Joule heat, whereby the temperature hardly reaches the melting point or softening point of the low resistance materials. Thus, the central portion 14d or the outer housing 14e formed of the low resistance material is not heated to be broken or deformed. Accordingly, a high electric current can continually flow into the contact portion 14c. Further, with low thermal conductivity, it is difficult to transfer the generated Joule heat to another member, e.g., the outer case 13 or the coil spring 15, thus preventing the malfunction of the pogo pins 12 due to thermal expansion of the outer case 13 or the coil spring 15.

The resistivity of the low resistance material is preferably about 10×10⁻⁸ Ω·m or less and more preferably in a range from about 1.6×10⁻⁸ Ω·m to 6×10⁻⁸ Ω·m. Further, the specific heat of the low resistance material is preferably about 1000 J/kgK or less and more preferably in a range from about 100 J/kgK to 500 J/kgK. In addition, the thermal conductivity of the low resistance material is preferably in a range from about 10 W/mK to 1000 W/mK and more preferably in a range from about 20 W/mK to 500 W/mK.

The low resistance material may include Au (gold), Ag (silver), Cu (copper), Cu/Au, Au/DLC (diamond like carbon), and Au/nanodiamond. The high abrasion resistant material may include Pt (white gold), Pd (palladium), W (tungsten), Rh (rhodium), Ni (nickel), DLC, Ni/DLC, Au/DLC, Au/nanodiamond, Ti (titanium), titanium alloys, copper alloys such as BeCu (beryllium copper), phosphor bronze or the like, and steel wires. Further, the material for the adhesion layer may include Ni, Ti, and Ta (tantalum). Appropriate combinations of the low resistance material, the material for the adhesion layer, and the high abrasion resistant material may include a combination of Au, Ni, and Pt, a combination Au, Ni, and W, a combination of Cu, Ni, and Au/DLC, a combination of Au, Ti, and Pt, and a combination of Au, Ti, and W, a combination of Au, Ta, and Pt, a combination of Au, Ta, W and the like.

Further, since the examination of the semiconductor device can be carried out as long as electric current flows in the contact portion 14c even if the central portion 14d and the outer housing 14e are separated from each other while the plunger 14 is repeatedly brought in contact with the electrode pad, the adhesion layer 14f may not be formed between the central portion 14d and the outer housing 14e.

In the plunger 14, the outer housing 14e is formed by depositing a high abrasion resistant material or a low resistance material around the central portion 14d. The outer housing 14e is formed by electrical casting, CVD (Chemical Vapor Deposition), PVD (Physical Vapor Deposition) or the like.

In the present embodiment, to obtain specified properties (i.e., abrasion resistance and high conductivity) of the central portion 14d and the outer housing 14e, the central portion 14d and the outer housing 14e need to have proper thickness. For example, in the first combination, the thickness (t) of the central portion 14d is in a range from about 0.5 μm to 50 μm, preferably in a range from about 3 μm to 50 μm, and the thickness (T) of the outer housing 14e is in a range from about 0.5 μm to 100 μm, preferably in a range from about 10 μm to 30 μm. Accordingly, the resistance of the central portion 14d can be maintained low, and thus an electric current smoothly flows the central portion 14d, thereby securely preventing the contact portion 14c from emitting a heat. In addition, the contact pressure between the outer housing 14e and the electrode pad can be maintained low, and thus the abrasion of the outer housing 14e is prevented, thereby securely preventing the contact portion 14c from being deformed.

Further, in the second combination, the thickness (t) of the central portion 14d is in a range from about 0.5 μm to 50 μm, preferably in a range from about 3 μm to 30 μm, and the thickness (T) of the outer housing 14e is in a range from 0.5 μm to 100 μm, preferably in a range from about 5 μm to 50 μm. Accordingly, the resistance of the outer housing 14e can be maintained low, and thus an electric current smoothly flows the outer housing 14e, thereby securely preventing the contact portion 14c from emitting a heat. In addition, the contact pressure between the central portion 14d and the electrode pad can be maintained low, and thus the abrasion of the central portion 14d is prevented, thereby securely preventing the contact portion 14c from being deformed.

While the present invention has been described with reference to the foregoing embodiments, it will be understood that the present invention is not limited to the illustrated embodiments.

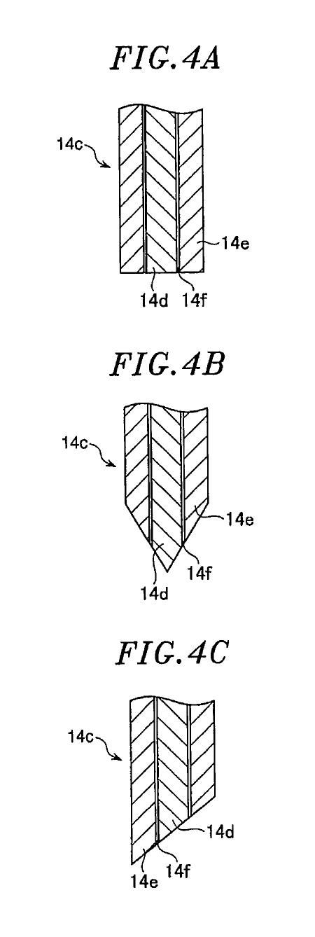

For example, although the contact portion 14c has the tip portion of cannon ball shape, the shape of the tip portion is not limited thereto. The tip portion may be cylinder end-shaped (FIG. 4A) or cone-shaped (FIG. 4B). Also, the tip portion may be formed by cutting the end portion of the contact portion 14c along a surface inclined with respect to the axis of the contact portion 14c (hereinafter, referred to as an inclined surface) (FIG. 4C). In the cylinder end-shaped tip portion, the contact portion 14c can be in surface contact with the electrode pad and substantially suppress the abrasion of the contact portion 14c. In the cone-shaped tip portion, even if the electrode pad is fine, the tip portion of the contact portion 14c is quite thin, and thus the contact portion 14c can be securely brought in contact with the electrode pad. Further, when the tip portion of the central portion 14c is cut along the inclined surface, the processing stages of the tip portion can be reduced and the tip portion can be easily formed.

In the foregoing embodiment, the contact portion 14c has a double-layered structure of the central portion 14d and the outer housing 14e. However, the contact portion 14c may have a structure of at least three stacked layers, wherein at least one layer includes a low resistance material and at least one layer includes a high abrasion resistant material. Further, although the plunger 14 has been illustrated as a cylindrical member, a member forming the plunger 14 is not limited to a cylindrical shape but may have, e.g., a prism shape. In the foregoing embodiment, the present invention is applied to the plunger of the pogo pin but may be applied to a contact portion of a contact probe.

In accordance with the present embodiment, since the hardness and the resistivity of a second material for an outer housing are different from the hardness and the resistivity of a first material for a central portion, any one of the outer housing and the central portion is not worn out to suppress the deformation of the main body and the other thereof smoothly flows an electric current to prevent the main body from heat emission, thus preventing the main body from being oxidized and damaged by melting.

While the invention has been shown and described with respect to the embodiments, it will be understood by those skilled in the art that various changes and modification may be made without departing from the scope of the invention as defined in the following claims.

What is claimed is:

1. A contact terminal for a probe card comprising a cylindrical main body,
wherein the main body includes a pillar-shaped central portion formed of a first material and an outer housing which is formed of a second material and covers a lateral surface of the central portion, and
hardness and resistivity of the second material are different from hardness and resistivity of the first material.

2. The contact terminal of claim 1, wherein the hardness of the second material is higher than that of the first material, and the resistivity of the first material is lower than that of the second material.

3. The contact terminal of claim 1, wherein the hardness of the first material is higher than that of the second material, and the resistivity of the second material is lower than that of the first material.

4. The contact terminal of claim 1, wherein a contact portion of the main body to be contacted with a semiconductor device is cone-shaped.

5. The contact terminal of claim 2, wherein a contact portion of the main body to be contacted with a semiconductor device is cone-shaped.

6. The contact terminal of claim 3, wherein a contact portion of the main body to be contacted with a semiconductor device is cone-shaped.

7. The contact terminal of claim 1, wherein a contact portion of the main body to be contacted with a semiconductor device has a cannon ball shape.

8. The contact terminal of claim 2, wherein a contact portion of the main body to be contacted with a semiconductor device has a cannon ball shape.

9. The contact terminal of claim 3, wherein a contact portion of the main body to be contacted with a semiconductor device has a cannon ball shape.

10. The contact terminal of claim 1, wherein a contact portion of the main body to be contacted with a semiconductor device is cylinder end-shaped.

11. The contact terminal of claim 2, wherein a contact portion of the main body to be contacted with a semiconductor device is cylinder end-shaped.

12. The contact terminal of claim 3, wherein a contact portion of the main body to be contacted with a semiconductor device is cylinder end-shaped.

13. The contact terminal of claim 1, wherein a contact portion of the main body to be contacted with a semiconductor device is formed by cutting the main body along a surface inclined with respect to an axis of the main body.

14. The contact terminal of claim 2, wherein a contact portion of the main body to be contacted with a semiconductor device is formed by cutting the main body along a surface inclined with respect to an axis of the main body.

15. The contact terminal of claim 3, wherein a contact portion of the main body to be contacted with a semiconductor device is formed by cutting the main body along a surface inclined with respect to an axis of the main body.

16. The contact terminal of claim 2, wherein the central portion has a thickness in a range from about 0.5 μm to 50 μm and the outer housing has a thickness in a range from about 0.5 μm to 100 μm.

17. The contact terminal of claim 3, wherein the central portion has a thickness in a range from about 0.5 μm to 50 μm and the outer housing has a thickness in a range from about 0.5 μm to 100 μm.

18. A probe card for examining a semiconductor device formed on a semiconductor substrate, the probe card comprising:
a plate-shaped base; and
contact terminals for the probe card disposed on a surface of the base facing the semiconductor substrate,
wherein each of the contact terminals includes a cylindrical main body,
the main body has a pillar-shaped central portion formed of a first material and an outer housing which is formed of a second material and covers a lateral surface of the central portion, and
hardness and resistivity of the second material are different from hardness and resistivity of the first material.
